(19) United States
(12) Patent Application Publication
(10) Pub. No.: US 2026/0073985 A1
(43) Pub. Date: Mar. 12, 2026

(54) ELECTRONIC DEVICE PROFILING NETWORK WITH IN-MEMORY COMPUTATION

(71) Applicant: NANYANG TECHNOLOGICAL UNIVERSITY, Singapore (SG)

(72) Inventors: Howe Li YEO, Singapore (SG); Gil Lampong Opina, JR., Singapore (SG); Anshuman Tripathi, Singapore (SG)

(21) Appl. No.: 19/323,880

(22) Filed: Sep. 9, 2025

Related U.S. Application Data
(60) Provisional application No. 63/692,625, filed on Sep. 9, 2024.

(51) Int. Cl. G11C 13/00; H02M 3/335

(52) U.S. Cl. CPC G11C 13/0069; G11C 13/0028; G11C 13/004; G11C 2213/71; H02M 3/33573

(57) ABSTRACT

A profiling system includes an in-memory computation system and an electronic device profiling system. The in-memory computation system includes computation circuitry and memristor control circuitry, the in-memory computation system profiling one or more electronic components that constitute an electronic device by computing component states of the electronic components based on parameters of the electronic components and a function defining a transformation of the parameters to the component states. The parameters are indicative of operating characteristics. The component states are indicative of states of health of the electronic components. The electronic device profiling system comprising device profiling circuitry, based on the component states at different time instances, predicts future component states of the electronic components, based on the predicted future component states, predicts one or more future device states of the electronic device, and outputs information of the predicted one or more future device states.

### CROSS REFERENCE TO RELATED APPLICATION

This present application claims priority to and benefits of U.S. Provisional Application No. 63/692,625, filed on Sep. 9, 2024, titled “In-Circuit Remaining Useful Life Estimation Of Power Converter Components Using Energy-Efficient Memristor-Based Computation-In-Memory Processor,” the content of which is hereby incorporated by reference in its entirety.

### TECHNICAL FIELD

This disclosure pertains to an electronic device profiling network that profiles an electronic device. Profiling an electronic device may include evaluating certain electronic device parameters to generate performance attributes of the electronic device.

### BACKGROUND

Reliability and longevity of power electronics are a growing concern. These power electronics may be implemented in renewable energy, distribution-level solid-state transformers and traction, in which the power electronics may be expected to operate for decades. Power electronics devices and components need to be evaluated to ensure ongoing safe operation and to track performance degradation.

### SUMMARY

A claimed solution rooted in computer technology overcomes problems specifically arising in the realm of computer technology. In some embodiments, to identify unsafe, ineffective, or inefficient operations of an electronic device, an electronic device profiling network profiles an electronic device. In some embodiments, profiling includes determining or inferring a remaining useful life (RUL) of the electronic device. In some embodiments, an electronic device includes one or more converters such as dual active bridges (DABs), or an electronic system.

In some embodiments, the electronic device profiling network includes an electronic component profiling system and an electronic device profiling system. The electronic component profiling system may be configured to profile one or more electronic components that constitute the electronic device. In some embodiments, the electronic components include a portion of the electronic device, such as one or more bridges of a converter. In some embodiments, at least a portion of the electronic components include subcomponents such as one or more transistors.

Profiling may include obtaining one or more component states corresponding to the electronic components. In some embodiments, the component states include quantitative indicators of state of health of the electronic components or subcomponents thereof. In some embodiments, the component states include on-resistances, junction-to-case thermal resistances, or equivalent series resistances of capacitors. In some embodiments, the electronic device profiling network obtains the component states based on one or more parameters. In some embodiments, parameters include electric, thermal, or other operating characteristics of the electronic components or subcomponents, or environmental characteristics. As nonlimiting examples, parameters may include ambient temperature, heatsink temperature or thermal resistance, casing temperature or thermal resistance, junction temperature or thermal resistance, component voltages of the electronic components, capacitor voltage ripple, output loading levels, ambient temperature, or relative humidity. In some embodiments, the electronic component profiling system obtains the parameters directly or indirectly from one or more sensors associated with the electronic components.

To obtain the one or more component states, the electronic component profiling system may perform computations on the parameters. The computations may include one or more matrix operations such as matrix vector multiplication. Performing computations may include generating a desired output (e.g., component states) based on an input (e.g., parameters) and a function describing a mapping or transformation between the input and the output. In some embodiments, the input is represented as an input vector, in which input vector elements correspond to the parameters. In some embodiments, the function is represented as a matrix such as a transformation matrix having matrix elements. In some embodiments, the electronic component profiling system generates a desired output based on matrix multiplication of the input vector and the transformation matrix.

The electronic component profiling system may include an in-memory computation system configured to perform the computations. In some embodiments, the in-memory computation system is a hardware system which includes random access memory and computation processors integrated within a same physical location. The in-memory computation system therefore combines computation of component states and memory capabilities (e.g., write and read) within the same physical location. This constitutes a technical improvement over other architectures that have separate central processing units (CPUs) and memory units because it eliminates or reduces data transfer between the separate central processing units (CPUs) and memory units which otherwise causes large energy overhead. The energy overhead may increase exponentially rather than linearly as the amount of data transferred increases. Overall, the in-memory computation system reduces power consumption, computing resource utilization, and latency, while increasing energy efficiency and computing parallelism. Moreover, the in-memory computation system may be non-volatile, meaning that they retain data even in absence of a power supply.

In some embodiments, the in-memory computation system includes a memristor array and memristor control circuitry. In some embodiments, the memristor array represents or models the function between the input and the output. For example, the memristor array may include a pattern of memristor cells programmed to have first electrical attribute magnitudes for a first electrical attribute (e.g., conductance). Each of the first electrical attribute magnitudes may represent a corresponding matrix element.

The memristor control circuitry may include input control circuitry configured to obtain the parameters and generate input signals based on the parameters. The input control circuitry may apply the input signals across the memristor cells. The input signals may include analog signals, in which corresponding second electrical attribute magnitudes of a second electrical attribute (e.g., voltage or current) represent values of the parameters or vector element values. Applying the input signals across the memristor cells may trigger change in electrical attributes across the memristor cells in accordance with certain electrical rules such as Ohm's law. The changed electrical attributes may result in third electrical attribute magnitudes corresponding to third electrical attributes (e.g., current or voltage).

The in-memory computation system may include output control circuitry configured to sense, capture, or detect (hereinafter “sense”) output signals based on the third electrical attribute magnitudes. In some embodiments, the output control circuitry may detect one or more read or write triggers. In response to a read or write trigger, the output control circuitry may be configured to convert the output signals to be suitable for storage, write the output signals into corresponding memristor cells, and retrieve the output signals from at least a subset of the corresponding memristor cells.

From the output signals, the electronic device profiling system may be configured to profile a device. The electronic device profiling system may retrieve the output signals and translate the output signals into component states. The electronic device profiling system may obtain a time series for the component states of each component or a subset thereof, based on the component states and one or more previous component states. The electronic device profiling system may profile each component based on the time series, and profile a device based on the component profiles. In some embodiments, the electronic device profiling system is configured to profile each component by predict future component states of each component based on extrapolation of each time series. In some embodiments, the electronic device profiling system is configured to estimate a component remaining useful life (RUL) of each component based on a time instance at which the predicted future component state reaches a threshold value or a threshold condition (hereinafter “threshold condition”). The threshold condition may be indicative of component failure. In some embodiments, the electronic device profiling system is configured to estimate a device RUL by assigning, to the device, a shortest component RUL out of the component RULs.

As a result, the electronic device profiling system ensures notification of performance degradation of an electronic device, which may prevent unsafe or unsatisfactory operation.

In accordance with some embodiments, a profiling system comprises an electronic component profiling system which includes an in-memory computation system. The in-memory computation system comprises computation circuitry and computation control circuitry. The in-memory computation system is configured to profile one or more electronic components that constitute an electronic device by obtaining, from one or more sensors of the electronic components, parameters indicative of operating characteristics of electronic components; computing, by the computation control circuitry and according to programming of the computation circuitry, the component states of the electronic components based on the parameters and a function defining a transformation of the parameters to the component states. The component states are indicative of states of health of the electronic components. The profiling system includes an electronic device profiling system which comprising device profiling circuitry configured to perform: based on the computed component states and previous component states, predicting future component states of the electronic components; based on the predicted future component states, predicting one or more future device states of the electronic device; and outputting information of the predicted one or more future device states.

In accordance with some embodiments, a method is implemented by a profiling system, the profiling system comprising an electronic component profiling system having an in-memory computation system, the in-memory computation system comprising computation circuitry and computation control circuitry. The profiling system comprises an electronic device profiling system. The method comprises: obtaining, from one or more sensors of the electronic components, parameters indicative of operating characteristics of electronic components; computing, by the computation control circuitry and according to programming of the computation circuitry, component states of the electronic components based on the parameters of the electronic components and a function defining a transformation of the parameters to the component states; the component states indicative of states of health of the electronic components; based on the computed component states and previous component states, predicting, by the electronic device profiling system, future component states of the electronic components; based on the predicted future component states, predicting, by the electronic device profiling system, one or more future device states of the electronic device; and outputting, by the electronic device profiling system, information of the predicted one or more future device states.

With regard to either the profiling system or the method, in some embodiments, predicting the future component states may comprise: predicting corresponding future time instances at which the future component states initially cross a threshold failure condition; and predicting one or more future device states may comprise: based on an earliest predicted future time instance, predicting a remaining useful life (RUL) of the electronic device.

With regard to either the profiling system or the method, in some embodiments, the computation circuitry comprises word lines and bit lines of computation circuitry elements programmed according to a transformation matrix representing the function, the transformation matrix comprising rows and columns of matrix elements, each column of matrix elements corresponding to a different electronic component and each bit line of the computation circuitry elements representing a component state of a different electronic component; and the computation control circuitry is configured to compute the component states by: generating input electric signals according to values of the parameters; applying the input electric signals to word lines of corresponding programmed computation circuitry elements to cause changes of electrical attribute magnitudes across the computation circuitry elements, a same input electric signal being applied to programmed computation circuitry elements across a particular word line; sensing the changes of electrical attribute magnitudes; and computing the component states based on the sensed changes of the electrical attribute magnitudes.

With regard to either the profiling system or the method, in some embodiments, the computation circuitry elements are programmed to have first electric attribute values of a first electric attribute consistent with the rows and columns of matrix elements; generating the input electric signals comprises programming the input electric signals according to second electric attribute values of a second electric attribute, the second electric attribute values being consistent with the values of the parameters; and the changes of electrical attribute magnitudes correspond to a third electric attribute.

With regard to either the profiling system or the method, in some embodiments, the first electric attribute comprises a conductance, the second electric attribute comprises a voltage, and the third electric attribute comprises a current.

With regard to either the profiling system or the method, in some embodiments, computing the component states based on the sensed changes of the electrical attribute magnitudes comprises: aggregating the changes of electrical attribute magnitudes across computation circuitry elements corresponding to a particular bit line to compute the component state of a particular electronic component corresponding to the particular bit line.

With regard to either the profiling system or the method, in some embodiments, the in-memory computation system comprises read/write trigger control circuitry configured to: generate a write trigger or a read trigger to cause the changes of electrical attribute magnitudes to be written into or read from memory cells corresponding to the computation circuitry elements, the memory cells being colocated with the computation circuitry elements; and apply the write trigger or the read trigger to one or more bit lines of the computation circuitry elements in response to applying of the input electric signals to word lines of corresponding programmed computation circuitry elements.

With regard to either the profiling system or the method, in some embodiments, the write trigger comprises a first voltage pulse and the read trigger comprises a second voltage pulse, the write trigger having a higher magnitude compared to the read trigger.

With regard to either the profiling system or the method, in some embodiments, the in-memory computation system comprises output control circuitry configured to: detect the write trigger or the read trigger; in response to detecting the write trigger or the read trigger, write the changes of electrical attribute magnitudes to one or more memory cells or retrieving the changes of electrical attribute magnitudes from one or more memory cells corresponding to selected computation circuitry elements indicated by the write trigger or the read trigger.

With regard to either the profiling system or the method, in some embodiments, the in-memory computation system comprises a memristor array.

These and other features of the systems, methods, and non-transitory computer readable media disclosed herein, as well as the methods of operation and functions of the related elements of structure and the combination of parts and economies of manufacture, will become more apparent upon consideration of the following description and the appended claims by referring to the accompanying drawings, all of which form a part of this specification, wherein like reference numerals designate corresponding parts in the various figures. It is to be expressly understood, however, that the drawings are for purposes of illustration and description only and are not intended as a definition of limits of the invention.

### BRIEF DESCRIPTION OF THE DRAWINGS

FIG. 1 is a diagram of an electronic device profiling network, according to some embodiments.

FIG. 2A is a diagram of a memristor array that includes memristor cells, according to some embodiments.

FIGS. 2B and 2C are diagrams of different resistance statuses of a memristor cell, according to some embodiments.

FIG. 3 is a diagram of an in-memory computation system, according to some embodiments.

FIG. 4 is a diagram of an in-memory computation method, according to some embodiments.

FIG. 5 is a diagram of an electronic component profiling network, according to some embodiments.

FIG. 6 is a diagram that illustrates example component state data, according to some embodiments.

### DETAILED DESCRIPTION

A claimed solution rooted in computer technology overcomes problems specifically arising in the realm of computer technology. In some embodiments, to identify unsafe, ineffective, or inefficient operations of an electronic device, an electronic device profiling network profiles an electronic device. In some embodiments, profiling includes determining or inferring a remaining useful life (RUL) of the electronic device. In some embodiments, an electronic device includes one or more converters such as dual active bridges (DABs), or an electronic system.

In some embodiments, the electronic device profiling network includes an electronic component profiling system and an electronic device profiling system. The electronic component profiling system may be configured to profile one or more electronic components that constitute the electronic device. In some embodiments, the electronic components include a portion of the electronic device, such as one or more bridges of a converter. In some embodiments, at least a portion of the electronic components include subcomponents such as one or more transistors.

Profiling may include obtaining one or more component states corresponding to the electronic components. In some embodiments, the component states include quantitative indicators of state of health of the electronic components or subcomponents thereof. In some embodiments, the component states include on-resistances, junction-to-case thermal resistances, or equivalent series resistances of capacitors. In some embodiments, the electronic device profiling network obtains the component states based on one or more parameters. In some embodiments, parameters include electric, thermal, or other operating characteristics of the electronic components or subcomponents, or environmental characteristics. As nonlimiting examples, parameters may include ambient temperature, heatsink temperature or thermal resistance, casing temperature or thermal resistance, junction temperature or thermal resistance, component voltages of the electronic components, capacitor voltage ripple, output loading levels, ambient temperature, or relative humidity. In some embodiments, the electronic component profiling system obtains the parameters directly or indirectly from one or more sensors associated with the electronic components.

To obtain the one or more component states, the electronic component profiling system may perform computations on the parameters. The computations may include one or more matrix operations such as matrix vector multiplication. Performing computations may include generating a desired output (e.g., component states) based on an input (e.g., parameters) and a function describing a mapping or transformation between the input and the output. In some embodiments, the input is represented as an input vector, in which input vector elements correspond to the parameters. In some embodiments, the function is represented as a matrix such as a transformation matrix having matrix elements. In some embodiments, the electronic component profiling system generates a desired output based on matrix multiplication of the input vector and the transformation matrix.

The electronic component profiling system may include an in-memory computation system configured to perform the computations. In some embodiments, the in-memory computation system is a hardware system which includes random access memory and computation processors integrated within a same physical location. The in-memory computation system therefore combines computation of component states and memory capabilities (e.g., write and read) within the same physical location. This constitutes a technical improvement over other architectures that have separate central processing units (CPUs) and memory units because it eliminates or reduces data transfer between the separate central processing units (CPUs) and memory units which otherwise causes large energy overhead. The energy overhead may increase exponentially rather than linearly as the amount of data transferred increases. Overall, the in-memory computation system reduces power consumption, computing resource utilization, and latency, while increasing energy efficiency and computing parallelism. Moreover, the in-memory computation system may be non-volatile, meaning that they retain data even in absence of a power supply.

In some embodiments, the in-memory computation system includes a memristor array and memristor control circuitry. In some embodiments, the memristor array represents or models the function between the input and the output. For example, the memristor array may include a pattern of memristor cells programmed to have first electrical attribute magnitudes for a first electrical attribute (e.g., conductance). Each of the first electrical attribute magnitudes may represent a corresponding matrix element.

The memristor control circuitry may include input control circuitry configured to obtain the parameters and generate input signals based on the parameters. The input control circuitry may apply the input signals across the memristor cells. The input signals may include analog signals, in which corresponding second electrical attribute magnitudes of a second electrical attribute (e.g., voltage or current) represent values of the parameters or vector element values. Applying the input signals across the memristor cells may trigger change in electrical attributes across the memristor cells in accordance with certain electrical rules such as Ohm's law. The changed electrical attributes may result in third electrical attribute magnitudes corresponding to third electrical attributes (e.g., current or voltage).

The in-memory computation system may include output control circuitry configured to sense, capture, or detect (hereinafter “sense”) output signals based on the third electrical attribute magnitudes. In some embodiments, the output control circuitry may detect one or more read or write triggers. In response to a read or write trigger, the output control circuitry may be configured to convert the output signals to be suitable for storage, write the output signals into corresponding memristor cells, and retrieve the output signals from at least a subset of the corresponding memristor cells.

From the output signals, the electronic device profiling system may be configured to profile a device. The electronic device profiling system may retrieve the output signals and translate the output signals into component states. The electronic device profiling system may obtain a time series for the component states of each component or a subset thereof, based on the component states and one or more previous component states. The electronic device profiling system may profile each component based on the time series, and profile a device based on the component profiles. In some embodiments, the electronic device profiling system is configured to profile each component by predict future component states of each component based on extrapolation of each time series. In some embodiments, the electronic device profiling system is configured to estimate a component remaining useful life (RUL) of each component based on a time instance at which the predicted future component state reaches a threshold value or a threshold condition (hereinafter “threshold condition”). The threshold condition may be indicative of component failure. In some embodiments, the electronic device profiling system is configured to estimate a device RUL by assigning, to the device, a shortest component RUL out of the component RULs.

As a result, the electronic device profiling system ensures notification of performance degradation of an electronic device, which may prevent unsafe or unsatisfactory operation.

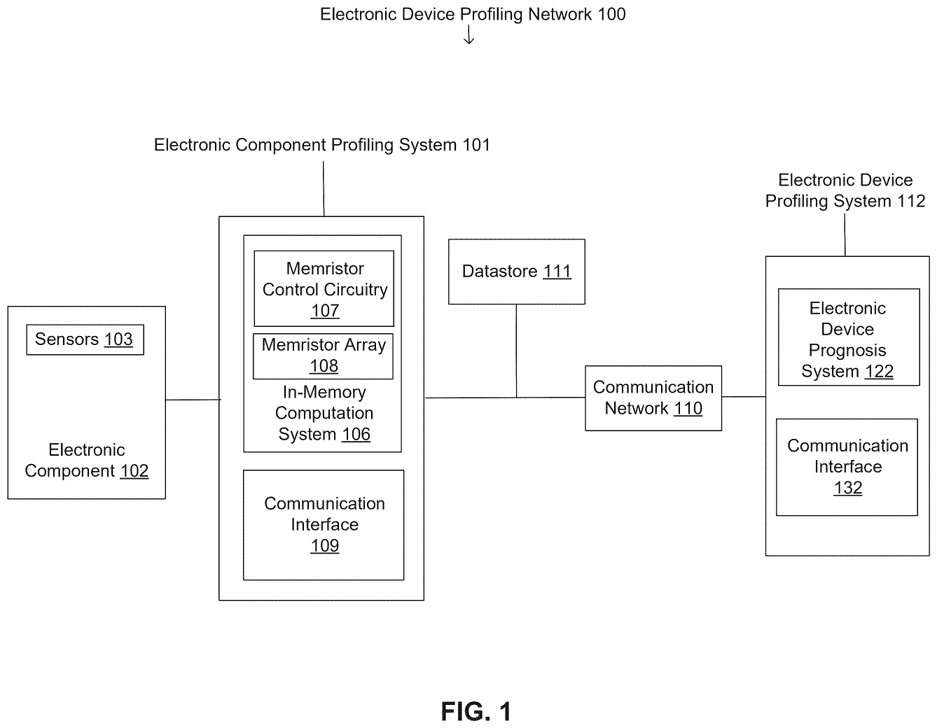

FIG. 1 is a diagram of an electronic device profiling network 100, which includes an electronic component profiling system 101 and an electronic device profiling system 112, according to some embodiments. The electronic component profiling system 101 may be configured to profile one or more electronic components 102 by determining one or more component states of the one or more electronic components 102, or of any subcomponents within the one or more electronic components 102. In some embodiments, the electronic component profiling system 101 is configured to profile the electronic components 102 while the electronic components are operating. In some embodiments, the electronic component profiling system 101 and the one or more electronic components 102 may form an electronic component profiling network. In some embodiments, each electronic component 102 is a constituent of an electronic device. For example, each electronic component 102 may include an individual bridge of a converter such as a dual active bridge (DAB). In some embodiments, the electronic component 102 includes an entire electronic device. In some embodiments, component states include any state of health indicators such as thermal resistances (e.g., junction-to-case thermal resistances), on-resistances when an electronic device is in an ON status, equivalent series resistance (ESR) of a capacitor, or power loss. Any reference to subcomponent may be understood to encompass a physical entity (e.g., a transistor within a bridge) within a component, an aspect of a component or a component state. For example, an aspect may include any factor or category that contributes to a component state, such as a thermal contribution or an electrical contribution.

In some embodiments, the electronic component profiling system 101 includes an in-memory computation system 106 configured to compute the component states based on parameters obtained directly or indirectly from one or more sensors 103. The parameters may include parameters such as ambient temperature, heatsink temperature or thermal resistance, casing temperature or thermal resistance, junction temperature or thermal resistance, component voltages of the electronic components, capacitor voltage ripple, output loading levels, ambient temperature, or relative humidity. The parameters may be selected based on a device type, component type, or availability of sensors.

To compute the one or more component states, the electronic component profiling system 101 may perform matrix operations such as matrix vector multiplication on the parameters. Performing computations may include generating a desired output (e.g., component states) based on an input (e.g., parameters) and a function between the input and the output. The function may be indicative of behaviors (e.g., thermal, electrical, physical response, or weighting behaviors) of one or more subcomponents or components 102. In some embodiments, the input is represented as an input vector, in which input vector elements correspond to the parameters. In some examples, each input vector element may correspond to a parameter of a subcomponent. In some embodiments, the function is represented as a transformation matrix, in which matrix elements correspond to different subcomponents and different components. In some embodiments, the electronic component profiling system 101 generates an output based on matrix multiplication of the input vector and the transformation matrix.

In some embodiments, the in-memory computation system 106 is a hardware system that includes random access memory such as resistive random access memory (ReRAM) and computation processors. The random access memory and the computation processors may be integrated within a same physical location. The in-memory computation system 106 therefore combines computation of component states and memory capabilities within the same physical location. This constitutes a technical improvement over other architectures that have separate central processing units (CPUs) and memory units because it eliminates or reduces data transfer between the separate central processing units (CPUs) and memory units which otherwise causes large energy overhead. Reduction of data transfer reduces power consumption, computing resource utilization, and latency, while increasing energy efficiency and computing parallelism. In some embodiments, the in-memory computation system 106 reduces the energy overhead by two orders of magnitude, while improving efficiency of communication protocol between computation and memory by 84 percent.

In some embodiments, the in-memory computation system 106 includes a memristor array 108. Although the description focuses on memristor arrays for the sake of illustration, it is understood that the description may be applicable to other embodiments which may include memristor or non-memristor arrays. For example, any reference to memristor arrays or memristor cells may also be applicable to computation circuitry and computation circuitry elements or cells, which may generally refer to memristor arrays or non-memristor arrays.

The memristor array 108 may represent the function between the input and the output. For example, the memristor array 108 may include a pattern of memristor cells programmed to have first electrical attribute magnitudes corresponding to a first electrical attribute (e.g., conductance). Each of the first electrical attribute magnitudes may represent a value of one matrix element. The memristor array 108 may be configured such that input signals of a second electrical attribute (e.g., voltage or current) having second electrical attribute magnitudes may be applied across the memristor array 108. Application of the input signals may trigger change in a third electrical attribute (e.g., current or voltage) across the memristor array 108. The input signals may include analog signals, in which corresponding second electrical attribute magnitudes (e.g., voltage or current) represent values of the parameters.

In some embodiments, the in-memory computation system 106 includes memristor control circuitry 107. Although the description focuses on memristor control circuitry, it is understood that the description may be applicable to more general circuitry which may include non-memristor control circuitry. For example, any reference to memristor control circuitry may also be applicable to computation control circuitry, which may generally refer to memristor control circuitry or non-memristor control circuitry.

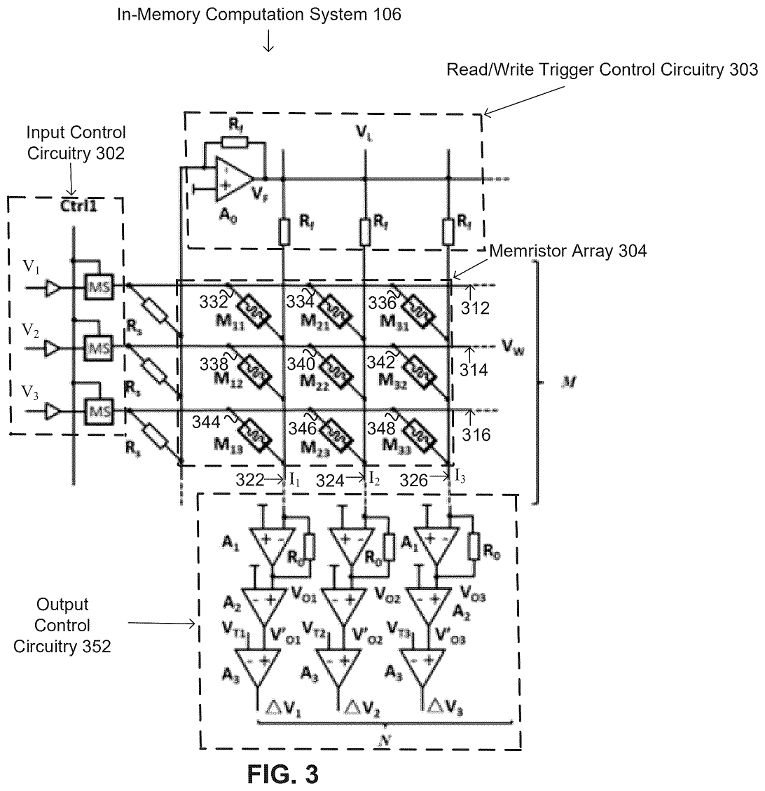

As will be further illustrated in FIG. 3, the memristor control circuitry 107 may include input control circuitry configured to obtain the parameters directly or indirectly from the sensors 103, and generate input signals having the second electrical attribute magnitudes according to the parameters. The input control circuitry may be configured to apply the input signals across the memristor array 108. Application of the input voltage signals may cause the memristor cells to have a third electrical attribute magnitude (e.g., current) across the memristor cells according to Ohm's law. In some examples, the third electrical attribute magnitudes corresponding to each memristor cell may each represent a subcomponent state.

In some embodiments, the memristor control circuitry 107 includes read/write trigger control circuitry. The read/write trigger control circuitry may be configured to control application of a write trigger or a read trigger to cause a write or read operation with respect to selected memristor cells. For example, the write trigger may include a first voltage or current pulse at a given magnitude, polarity, or duration. In some embodiments, the write trigger induces a resistance change that causes writing of a particular bit (e.g., logical “0” or “1”) depending on a polarity of the applied pulse. As another example, the read trigger may include a second voltage or current pulse at a lower magnitude or duration compared to the first voltage or current pulse. In some embodiments, the read trigger induces a smaller or negligible resistance chance in the memristors. In some embodiments, the read/write trigger control circuitry applies write triggers or read triggers across different transmission lines compared to the input signals.

In some embodiments, the read/write trigger control circuitry is configured to generate and apply a read/write trigger after the application of the input voltage signals by the input control circuitry. As a result, the read/write trigger control circuitry controls writing of output signals corresponding to the third electrical attribute magnitudes to memristor cells, and retrieval of the output signals from the memristor cells.

In some embodiments, the memristor control circuitry includes output control circuitry configured to sense output signals corresponding to the third electrical attribute magnitudes. For example, the output control circuitry may include a current model analog to digital converter (ADC). The output control circuitry may be configured to convert the output signals to be suitable for storage (e.g., via the ADC). The output control circuitry may additionally be configured to detect a write trigger or a read trigger, obtain one or more selected memristor cells designated or selected for a write or read operation, and perform one or more read or write operations accordingly.

In some embodiments, the electronic component profiling system 101 includes one or more communication interfaces 109 configured to communicate with the electronic device profiling system 112. In some embodiments, the communication interfaces 109 are configured to convert commands from the electronic component profiling system 101 or from the electronic device profiling system 112 into specific actions. For example, the communication interfaces 109 may be configured to generate component states based on the output signals and store the component states in on or more datastores 111.

The electronic device profiling system 112 may include device profiling circuitry (e.g., hardware, software, or firmware) configured to obtain the component states at the datastore 111 via a communication network 110 via one or more communication interfaces 132. However, in other embodiments, if the component states are not already stored in the datastore 111, the electronic device profiling system 112 may obtain at least a subset of the output signals. The electronic device profiling system 112 may be configured to translate the output signals into component states or otherwise obtain or generate component states from the output signals. In some embodiments, the electronic device profiling system 112 stores the component states corresponding to different time instances in the datastore 111. The electronic device profiling system 112 may store the component states in the datastore 111 at a fixed cadence (e.g., every week, every two weeks, every four weeks) or a variable cadence. The electronic device profiling system 112 may compare most updated component states with one or more previous component states corresponding to different time instances. The electronic device profiling system 112 may retrieve the previous component states from the datastore 111 for comparison.

The electronic device profiling system 112 may be configured to profile the device based on the component states. In some embodiments, the electronic device profiling system 112 includes an electronic device prognosis system 122. Prognosis may refer to estimating a RUL or other health statuses. The electronic device prognosis system 122 may generate a time series for the component states of each component or a subset of the components based on a comparison of most recent component states with previous component states. In some embodiments, the electronic device prognosis system 122 is configured to predict future component states based on extrapolation of each time series. For example, the electronic device prognosis system 122 is configured to predict future component states based on rate of change of component states, which may occur over two or more different time instances or over any time duration. In some embodiments, the electronic device prognosis system 122 is configured to estimate a component RUL based on a time instance at which the predicted future state reaches a threshold condition. In some embodiments, predicting future component states is based on an assumption of a linear or non-linear rate of change of the component state over time. In some embodiments, the electronic device prognosis system 122 is configured to estimate a device RUL by assigning, to the device, a device RUL corresponding to or based on a shortest component RUL out of the component RULs.

The electronic device prognosis system 122 may be configured to output a device RUL or component RULs. In some embodiments, the electronic device prognosis system 122 includes circuitry configured to diagnose or selectively perform physical or electronic transformations onto the device. These transformations may include shutting down or limiting operations of device or a component thereof if the device has been determined to have failed, or is approaching failure, based on the RUL. For example, the electronic device prognosis system 122 may divert electric current away from the device and towards a different device, such as a backup or auxiliary device, which has a higher RUL.

In some embodiments, the communication interfaces 132 are configured to convert commands from the electronic device prognosis system 122 into specific actions. As another example, the electronic device prognosis system 122 may generate commands to request component states, contextual data, device contextual data, other contextual data related to other devices, or environmental data. The component state data, component contextual data, and device contextual data may be reflected in different formats such as historical logs pertaining to the electronic components 102 or the device. This requested data may be stored in the one or more datastores 111 which may be implemented within physical or cloud-based servers. The one or more communication interfaces 132 may translate these commands and direct these commands to the datastores 111, retrieve the component state data, component or device contextual data, and communicate the component or device contextual data to the electronic device prognosis system 122. In some embodiments, the one or more communication interfaces 132 automatically transmit certain communications to the electronic device prognosis system 122. For example, the one or more communication interfaces 132 may automatically obtain updated component states from the electronic component profiling system 101 or from the one or more datastores 111. The communication interfaces 132 may be configured for two-way communication, including receiving or transmitting any communications from the communication interfaces 109 of the electronic component profiling system 101.

In some embodiments, the communication interfaces 109 or 132 are configured via control signals and/or user interfaces as needed. In some embodiments, the communication interfaces 109 or 132 communicate with a single interface or any number of interfaces. In some embodiments, the electronic device profiling system 112 may not contain a separate communication interface 132.

The communication network 110 may include any secured communication network such as an encrypted network. The communication network 110 may represent one or more computer networks (e.g., LAN, WAN, or the like) or other transmission mediums. The communication network 110 may provide communication within the electronic device profiling network 100 and/or between the electronic device profiling network 100 and other external systems or networks. In some embodiments, the communication network 110 includes one or more computing devices, routers, cables, buses, and/or other network topologies (e.g., mesh, and the like). In some embodiments, the communication network 110 may be wired and/or wireless. In various embodiments, the communication network 110 may include the Internet, one or more wide area networks (WANs) or local area networks (LANs), one or more networks that may be public, private, IP-based, non-IP based, and so forth.

The electronic device profiling system 112 may include one or more user interfaces that present one or more device or component prognosis results, diagnosis results, component states or device states. The user interfaces may include human machine interfaces (HMIs).

In some embodiments, the electronic device profiling system 112 may include the electronic component profiling system 101. In some embodiments, the electronic device profiling system 112 and the electronic component profiling system 101 may together constitute an electronic device management system or a profiling system.

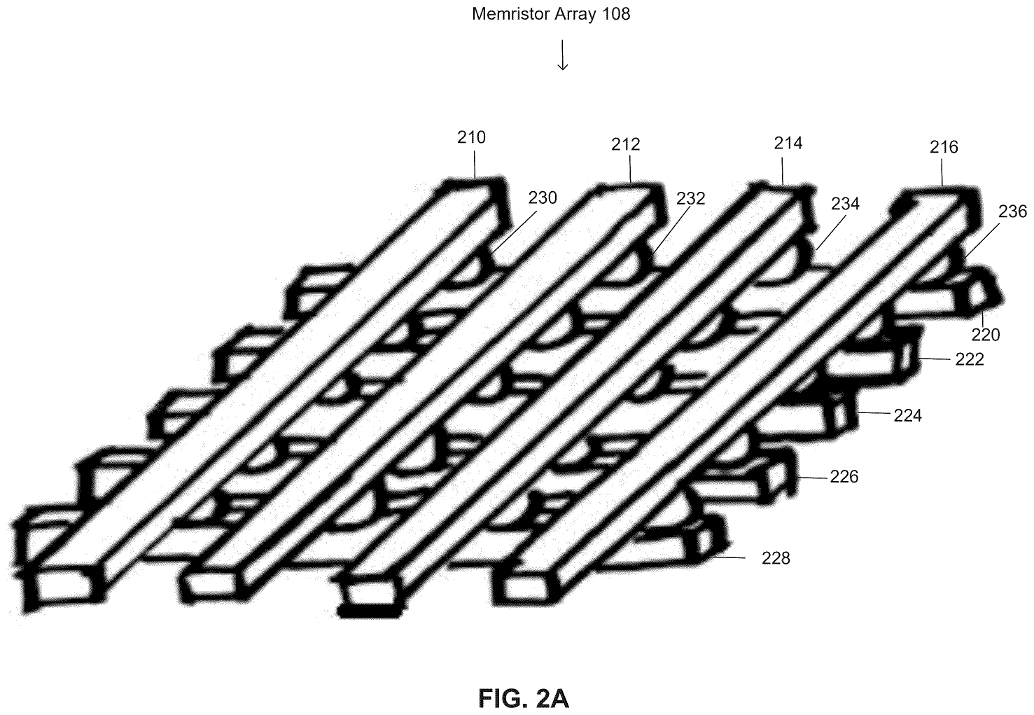

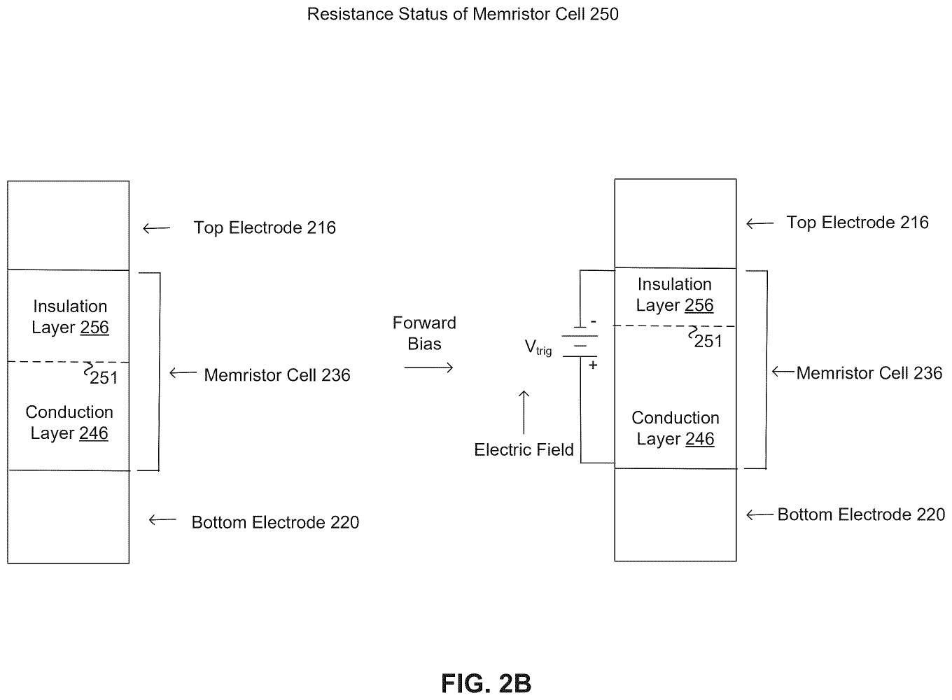

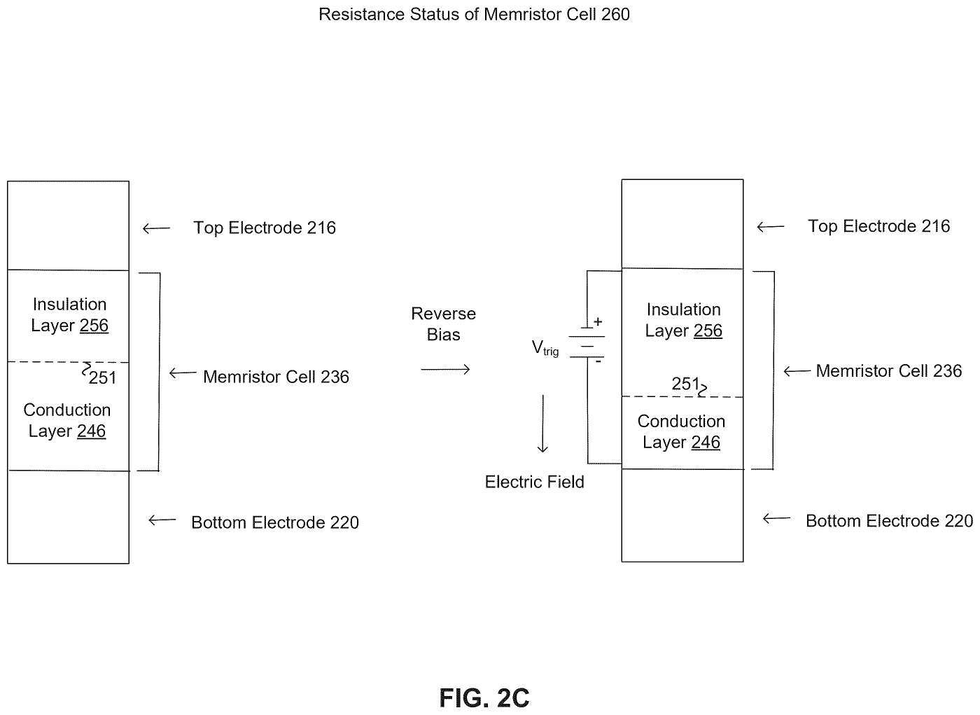

FIG. 2A is a diagram of the memristor array, according to some embodiments. Any principles described in FIG. 2A may be implemented in conjunction with any principles described above, such as in FIG. 1. In FIG. 2A, the memristor array 108 includes a crossbar or matrix architecture. In some embodiments, the memristor array 108 includes top electrodes 210, 212, 214, and 216, and bottom electrodes 220, 222, 224, 226, and 228. In some embodiments, the top electrodes 210, 212, 214, and 216, and the bottom electrodes 220, 222, 224, 226, and 228 are coupled to, or contact one another, at junctions, which correspond to memristor cells. The memristor cells illustrated in FIG. 2A include memristor cell 230 between the top electrode 210 and the bottom electrode 220, memristor cell 232 between the top electrode 210 and the bottom electrode 220, memristor cell 234 between the top electrode 214 and the bottom electrode 220, memristor cell 236 between the top electrode 216 and the bottom electrode 220. Other memristor cells, unlabeled for simplicity, include memristor cells between each of the top electrodes 210, 212, 214, and 216 and each of bottom electrodes 222, 224, 226, and 228. Thus, any reference to memristor cells 230, 232, 234, 236 may also be applicable to other unlabeled memristor cells. The memristor cells 230, 232, 234, 236 may correspond to an active area of the memristor array 204, or locations of memory cells within the memristor array 204. In some embodiments, the top electrodes 210, 212, 214, and 216 and the bottom electrodes 222, 224, 226, and 228 contain wires such as nanowires.

In some embodiments, the top electrodes 210, 212, 214, and 216 contain same or different materials compared to the bottom electrodes 220, 222, 224, 226, and 228. For example, the top electrodes 210, 212, 214, and 216 or the bottom electrodes 220, 222, 224, 226, and 228 may include copper, silver, platinum, or other metals which have varying degrees of activity, or other conductive materials such as indium tin oxide (ITO). In some embodiments, the memristor cells 230, 232, 234, 236 include a resistive switching layer having an insulating, semiconducting, or phase-change material, such as titanium dioxide, hafnium oxide, tantalum oxide, hexagonal boron nitride, molybdenum disulfide, palladium diselenide, hafnium diselenide, rhenium disulfide, black phosphorene, tungsten diselenide, tungsten disulfide, or tin sulfide. In some embodiments, the memristor cells 230, 232, 234, 236 have modifiable resistance statuses as illustrated in FIGS. 2B and 2C. Changes in resistance status may trigger write operations of the memristor cells 230, 232, 234, and 236, as will be described in FIGS. 2B and 2C.

In some embodiments, the bottom electrodes 220, 222, 224, 226, and 228 form word lines and the top electrodes 210, 212, 214, and 216 form bit lines perpendicular to the word lines. Depending on configuration, either the top electrodes 210, 212, 214, and 216 or the bottom electrodes 220, 222, 224, 226, and 228 may form the bit lines. The word lines may be designated for transmission of input signals (e.g., computation input signals) while the bit lines may be designated for transmission of read/write triggers.

FIGS. 2B and 2C illustrate different resistance statuses 250 and 260, respectively, of a memristor cell, according to some embodiments. Any principles described in FIG. 2B and FIG. 2C may be implemented in conjunction with any relevant principles described above, such as in FIG. 1 or FIG. 2A. In FIGS. 2B and 2C, applying a write trigger signal (e.g., voltage) of a forward polarity or a reverse polarity causes a change in resistance status of the memristor cell 236, thereby causing the memristor cell 236 to perform a write operation. Although FIGS. 2B and 2C illustrate the memristor cell 236, the top electrode 216, and the bottom electrode 220, principles illustrated in FIGS. 2B and 2C are also applicable to other memristor cells.

In some embodiments, the memristor cells 230, 232, 234 include a conduction layer 246 corresponding to a doping region (e.g., having oxygen vacancies) and an insulating layer 256 corresponding to an undoped region. A boundary 251 separates the conduction layer 246 and the insulating layer 256. Movement of the boundary 251 may occur due to electron movement within the memristor cell 236 caused by application of voltage in forward or reverse bias. This movement may cause change in resistance status of the memristor cell 236.

In FIG. 2B, the memristor control circuitry 107, in particular, the write/read triggering control circuitry, may generate and apply a write trigger signal of a forward polarity and a magnitude V_{trig} across the memristor cell 236. This causes an electric field within the memristor cell 236, which results in movement of the oxygen vacancies towards a negative terminal. The movement of oxygen vacancies may cause creation of conductive filaments, which causes movement of the boundary 251 and expansion of the conduction layer 246. In some embodiments, expansion of the conduction layer 246 results in change in resistance status, for example, to a low resistance state (LRS). In some embodiments, the LRS causes the memristor cell 236 to write a logical “1.”

In FIG. 2C, the memristor control circuitry 107, in particular, the write/read triggering control circuitry, may generate and apply a write trigger signal of a reverse polarity and a magnitude V_{trig} across the memristor cell 236. This causes an electric field in an opposite direction within the memristor cell 236, which results in movement of the oxygen vacancies towards a positive terminal. The movement of oxygen vacancies may cause rupturing of conductive filaments, which causes movement of the boundary 251 and contraction of the conduction layer 246. In some embodiments, contraction of the conduction layer 246 results in change in resistance status, for example, to a high resistance state (HRS). In some embodiments, the LRS causes the memristor cell 236 to write a logical “0.”

In some embodiments, the principles described in FIGS. 2B and 2C may be expanded if the memristor cell 236 has other resistance statuses besides the LRS and the HRS, such as intermediate resistance states (IRS). In some embodiments, if more than two resistance statuses are implemented, then each resistance status may cause the memristor cell 236 to write a plurality of bits. For example, if the memristor cell 236 has a HRS, a LRS, and two IRSs, then at each resistance status, the memristor cell 236 may write two bits instead of one bit.

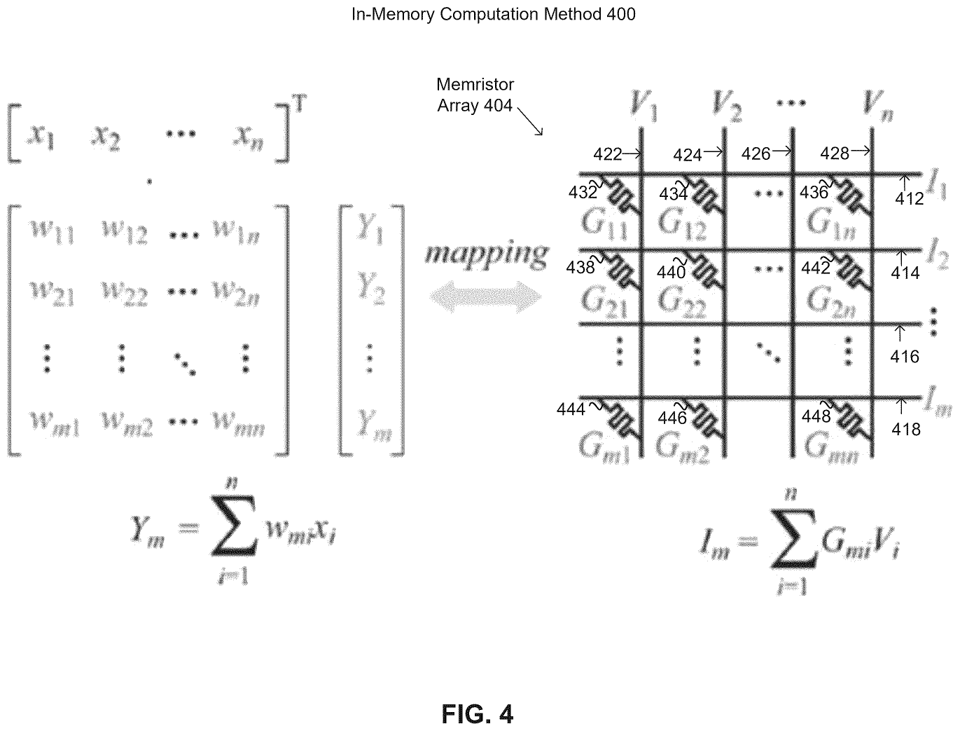

While FIGS. 2A-2C focus on an example physical layout of the memristor array 108, FIGS. 3-4 focus on the memristor control circuitry 107 of the in-memory computation system 106. Any principles described in FIG. 3 may be implemented in conjunction with any principles described above, such as in FIGS. 1, 2A-2C. In FIG. 3, the in-memory computation system 106 may include a memristor array 304. In some embodiments, any relevant principles previously described with regard to memristor array 108 may also be applicable to the memristor array 304. In some embodiments, the memristor array 304 includes a crossbar or matrix architecture. In some embodiments, the memristor array 304 includes word lines 312, 314, and 316 and bit lines 322, 324, and 326. Here, the word lines 312, 314, and 316 correspond to different rows. However, in other implementations, word lines may correspond to different columns instead of rows, as shown, for example, in FIG. 4. In some embodiments, the memristor array 304 includes memristor cells 332, 334, 336, 338, 340, 342, 344, 346, and 348. The memristor cells 332, 334, 336, 338, 340, 342, 344, 346, and 348 may have first electrical attribute magnitudes M₁₁, M₂₁, M₃₁, M₁₂, M₂₂, M₃₂, M₁₃, M₂₃, and M₃₃, respectively.

In some embodiments, the first electrical attribute may correspond to a conductance (e.g., reciprocal of resistance). The first electrical attribute magnitudes may be programmed according to the transformation matrix, or the function between the inputs (e.g., parameters) and the desired outputs of computation (e.g., component or subcomponent states). In some embodiments, the first electrical attribute magnitudes are represented generally as Mᵢⱼ where i indicates a particular component and j indicates a particular subcomponent.

The in-memory computation system 106 may include memristor control circuitry 107, which may include any or all of input control circuitry 302, read/write trigger control circuitry 303, and output control circuitry 352. In some embodiments, the input control circuitry 302 is configured to obtain the parameters directly or indirectly from the sensors 103. The input control circuitry 302 may be configured to generate or obtain input signals (e.g., analog signals) having a second electrical attribute magnitude of a second electrical attribute (e.g., voltage). The input control circuitry 302 may be configured to apply the input signals across the memristor cells 332, 334, 336, 338, 340, 342, 344, 346, and 348. For example, the input signals may include voltage signals V₁, V₂, V₃, meaning that the second electrical attribute corresponds to a voltage. Magnitudes of the voltage signals V₁, V₂, V₃ may represent values of the parameters. Each voltage signal V₁, V₂, V₃ may represent a parameter of a subcomponent. In some embodiments, during applying of the input signals, the input control circuitry 302 maintains the bit lines 322, 324, and 326 in a grounded status.

In the example of FIG. 3, a voltage signal V₁ may be applied to the word line 312, meaning that the voltage signal V₁ is applied across the memristor cells 332, 334, and 336 (e.g., each memristor cell has an applied voltage across its respective terminals). In other words, a same magnitude voltage signal may be applied across each memristor cell in a given word line. A voltage signal V₂ may be applied to the word line 314, meaning that the voltage signal V₂ is applied across the memristor cells 338, 340, and 342. A voltage signal V₃ may be applied to the word line 316, meaning that the voltage signal V₃ is applied across the memristor cells 344, 346, and 348. Application of the input voltage signals may cause corresponding memristor cells to have a third electrical attribute magnitude (e.g., a current), according to certain electrical rules such as Ohm's law. For example, application of input voltage V₁ applied across the memristor cell 332 may result in a current through the memristor cell 332 of a magnitude V₁*M₁₁. Application of input voltage V₁ across the memristor cell 334 may result in a current through the memristor cell 334 having a magnitude V₁*M₂₁. Application of input voltage V₁ across the memristor cell 336 may result in a current through the memristor cell 336 having a magnitude V₁*M₃₁. Application of input voltage V₂ across the memristor cell 338 may result in a current through the memristor cell 338 having a magnitude V₂*M₁₂. Application of input voltage V₂ across the memristor cell 340 may result in a current through the memristor cell 340 having a magnitude V₂*M₂₂. Application of input voltage V₂ across the memristor cell 342 may result in a current through the memristor cell 342 having a magnitude V₂*M₃₂. Application of input voltage V₃ across the memristor cell 344 may result in a current through the memristor cell 344 having a magnitude V₃*M₁₃. Application of input voltage V₃ across the memristor cell 346 may result in a current through the memristor cell 346 having a magnitude V₃*M₂₃. Application of input voltage V₃ across the memristor cell 348 may result in a current through the memristor cell 348 having a magnitude V₃*M₃₃. In some embodiments, the aforementioned individual current magnitudes represent subcomponent states.

In some embodiments, summed current magnitudes I₁, I₂, and I₃ represent aggregate currents through the memristor cells across a given bit line. In some embodiments, the summed current magnitudes I₁, I₂, and I₃ may be sensed or obtained by output control circuitry 352 as output signals at the ends of bit lines 322, 324, and 326. For example, the summed current magnitude I₁ is obtained by aggregating the currents through the memristor cells 332, 338, and 344 according to Kirchoff's law. The summed current magnitude I₂ may be obtained by aggregating the currents through the memristor cells 334, 340, and 346. The summed current magnitude I₃ may obtained by aggregating the currents through the memristor cells 336, 342, and 348. In some embodiments, each of the summed current magnitudes I₁, I₂, and I₃ represent component states. Thus, the in-memory computing system 106 performs matrix multiplication and summation by leveraging Ohm's law and Kirchoff's law. The summed current magnitudes I₁, I₂, and I₃ may be computed or sensed in parallel, which constitutes a further technical benefit compared to older von Neumann architectures in which certain computations could not be made in parallel.

In some embodiments, instead of the second electrical attribute being voltage, the second electrical attribute may be a current. Then, the third electrical attribute may be a voltage and the first electrical attribute may be a resistance. In some embodiments, the word lines may be oriented vertically instead of horizontally while the bit lines may be oriented horizontally instead of vertically.

In some embodiments, the read/write trigger control circuitry 303 is configured to control application of a write trigger or a read trigger to cause a write or read operation with respect to at least a subset of memristor cells. In some embodiments, the write trigger or the read trigger identifies selected memristor cells to perform a write or read operation. The read/write trigger control circuitry 303 may control application of the write trigger or the read trigger through any or all of the bit lines 322, 324, and 326. If the read/write trigger control circuitry 303 applies a write trigger or a read trigger through the bit line 322, the write trigger or the read trigger may cause any of the individual current magnitudes corresponding to the memristor cells 332, 338, or 344 to be written or read. In some embodiments, the read/write trigger control circuitry 303 is configured to control a timing of the application of a write trigger or a read trigger to occur after the input control circuitry has applied an input voltage across the memristor array 304. For example, the read/write trigger control circuitry 303 may be configured to detect that the input control circuitry 302 has applied the input signals across any of the word lines 312, 314, and 316, and in response to detecting the application of the input signals, generate or apply a write trigger or read trigger.

In some embodiments, the output control circuitry 352 is configured to sense output signals corresponding to the third electrical attribute magnitudes (e.g., any of the individual current magnitudes or a summed current magnitude 11, 12, or 13). The output control circuitry 352 may include a current model analog to digital converter (ADC). The output control circuitry 352 may be configured to convert the output signals to be suitable for storage (e.g., via the ADC). The output control circuitry 352 may additionally or alternatively be configured to detect a write trigger or a read trigger and perform one or more read or write operations accordingly. In some embodiments, the output control circuitry 352 includes one or more amplifiers, such as operational amplifiers, inverted amplifiers, or inverted operational amplifiers. In some embodiments, the output control circuitry 352 may amplify a read trigger in order to detect the read trigger. In some embodiments, the output control circuitry 352 includes separate output control circuitry for each bit line 322, 324, and 326.

FIG. 4 is a diagram of an example in-memory computation method 400. Any principles described in FIG. 4 may be implemented in conjunction with any principles described above, such as in FIGS. 1, 2A-2C and 3. FIG. 4 illustrates how a memristor array 404 is programmed to perform a computation. In some embodiments, any relevant principles described with regard to the memristor arrays 108 or 304 may also apply to the memristor array 404. The memristor array 404 may include memristor cells 432, 434, 436, 438, 440, 442, 444, 446, and 448, among other memristor cells not shown. In some embodiments, the memristor array 404 includes word lines 422, 424, 426, and 428 and bit lines 412, 414, 416, and 418. Notably, in FIG. 4, the word lines 422, 424, 426, and 428 are oriented vertically instead of horizontally, as was illustrated in FIG. 3. In FIG. 4, the memristor array 404 may be programmed according to a computation objective. Assume that the computation objective is to obtain component states Yₘ from matrix multiplication of parameters represented by vector xᵢ and a function Wₘᵢ between the parameters and component states Yₘ, such that

$${Y}_{m} = {\sum }_{i = 1}^{n} {W}_{m i} {x}_{i} .$$

In some examples, i may represent different subcomponents.

The memristor array 404 may be programmed according to

$${I}_{m} = {\sum }_{i = 1}^{n} {G}_{m i} {V}_{i}$$

such that conductances Gₘᵢ across the memristor cells 432, 434, 436, 438, 440, 442, 444, 446, and 448 represent the function Wₘᵢ, the input voltage V₁ represents the parameters xᵢ, and the output current Iₘ (e.g., summed current magnitudes) across the bit lines 412, 414, 416, and 418 represents the component states Yₘ. The memristor cells 432, 434, 436, 438, 440, 442, 444, 446, and 448 may have first electrical attribute magnitudes G₁₁, G₁₂, G₁ₙ, G₂₁, G₂₂, G₂ₙ, Gₘ₁, Gₘ₂, and Gₘₙ, respectively. In some embodiments, the first electrical attribute may correspond to a conductance (e.g., reciprocal of resistance). In some embodiments, the first electrical attribute magnitudes are represented generally as Gₘₙ where m indicates a particular component and n indicates a particular subcomponent.

In some embodiments, the input voltage includes input voltage signals V₁, V₂, Vₙ meaning that the second electrical attribute corresponds to a voltage. Magnitudes of the input voltage signals V₁, V₂, Vₙ may represent values of the parameters. Each voltage signal may represent a value of a parameter corresponding to a subcomponent. In the example of FIG. 4, a voltage signal V₁ may be applied to the word line 442, meaning that the voltage signal V₁ is applied across the memristor cells 432, 438, and 444 (e.g., each memristor cell has an applied voltage V₁ across its respective terminals). A voltage signal V₂ may be applied to the word line 424, meaning that the voltage signal V₂ is applied across the memristor cells 434, 440, and 446. A voltage signal Vₙ may be applied to the word line 428, meaning that the voltage signal Vₙ is applied across the memristor cells 436, 442, and 448.

Application of the voltage signals may cause corresponding memristor cells to have a third electrical attribute magnitude (e.g., a current). For example, application of input voltage V₁ applied across the memristor cell 432 may result in a current through the memristor cell 432 of a magnitude V₁*G₁₁. Application of input voltage V₁ applied across the memristor cell 438 may result in a current through the memristor cell 438 having a magnitude V₁*G₂₁. Application of input voltage V₁ applied across the memristor cell 444 may result in a current through the memristor cell 444 having a magnitude V₁*Gₘ₁. Application of input voltage V₂ applied across the memristor cell 434 may result in a current through the memristor cell 434 having a magnitude V₂*G₁₂. Application of input voltage V₂ applied across the memristor cell 440 may result in a current through the memristor cell 440 having a magnitude V₂*G₂₂. Application of input voltage V₂ applied across the memristor cell 446 may result in a current through the memristor cell 446 having a magnitude V₂*Gₘ₂. Application of input voltage V₃ applied across the memristor cell 436 may result in a current through the memristor cell 436 having a magnitude V₁*G₁ₙ. Application of input voltage V₃ applied across the memristor cell 442 may result in a current through the memristor cell 442 having a magnitude Vₙ*G₂ₙ. Application of input voltage Vₙ applied across the memristor cell 348 may result in a current through the memristor cell 348 having a magnitude Vₙ*Gₘₙ. In some embodiments, the aforementioned individual current magnitudes represent subcomponent states.

In some embodiments, summed current magnitudes I₁, I₂, and Iₘ at the ends of bit lines 412, 414 and 418 are obtained by aggregating the currents through the memristor cells in each bit line. For example, the summed current magnitude I₁ may be obtained by aggregating the currents through the memristor cells 432, 434, and 436. In some embodiments, each of the summed current magnitudes I₁, I₂, and Iₘ represent component states which may be obtained by the electronic device profiling system 112.

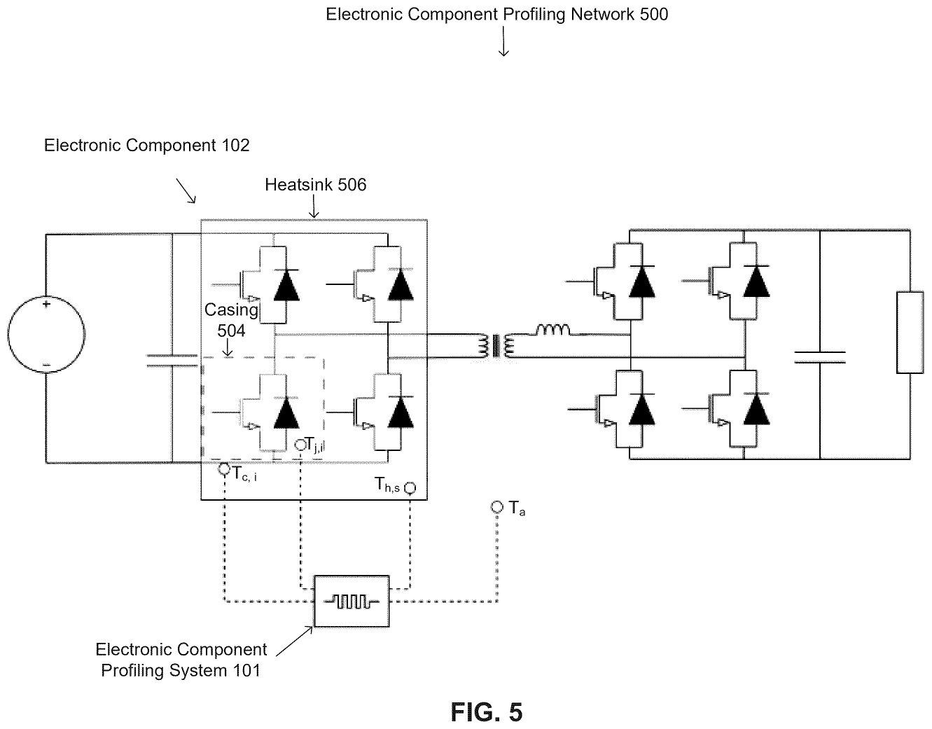

FIG. 5 illustrates an example electronic component profiling network 500. In FIG. 5, the electronic component profiling network 500 may include the electronic component 102 and the electronic component profiling system 101. The electronic component profiling system 101 may be configured to profile one or more electronic components such as the electronic component 102. Here, the electronic components may be part of an electronic device, which may include a power transistor assembly. The electronic component profiling system 101 may profile the electronic components by obtaining component states for components m, such as a degradation factor kₘ which relates present or degraded thermal resistance, R_{th,deg} and an initial thermal resistance R_{th,new} when the electronic components were brand new. Equations governing the electronic components may include:

$${R}_{th , d e g} = {k}_{m} \cdot {R}_{th , n e w}$$

$${P}_{L , 1} + {P}_{L , 2} + {P}_{L , 3} + {P}_{L , 4} = \frac{{T}_{h s} - {T}_{a}}{{R}_{h s}}$$

$${P}_{L , i} = \frac{{T}_{j , i} - {T}_{c , i}}{{k}_{t , i} {R}_{th , new}}$$

T_{j,i} may be a junction temperature for subcomponent i (e.g., an individual switch or alternatively, multiple switches) which can be either directly measured by the sensors 103 or inferred by measuring thermally sensitive electrical parameters. T_{c,i} may be a casing temperature measured on a thermally conductive portion of a casing 504, Tₕₛ may be a heatsink temperature, T_{α} may be an ambient temperature of ambient air measured away from the casing 504, and P_{L,i} may be a power loss by subcomponent i. k_{t,m} may be a degradation factor for component m at a time instance t. In some embodiments, the ambient temperature may be measured farther away from the casing 504. In some embodiments, degradation factor for a particular subcomponent may be used instead of for the component.

Computing the degradation factors may include matrix operations across different subcomponents, which may be programmed by the in-memory computation system 106 (e.g., any of the in-memory computation systems illustrated in FIG. 2A, 3, or 4).

In some embodiments, a simplifying assumption is that all subcomponents i may have same power losses, which yields the following equation governing expected power loss per component:

$$4 \cdot {P}_{L} = \frac{{T}_{h s} - {T}_{a}}{{R}_{h s}} .$$

Observed power loss P_{obs,i} may be computed using

$${P}_{o b s , i} = \frac{{T}_{j , i} - {T}_{c , i}}{{R}_{th , new}} .$$

It is expected that due to the degradation, the observed power loss may differ from expected power loss by a factor of k_{t,m}. Therefore, k_{t,m} for a time instance may be computed using

$${k}_{t , m} = \frac{{P}_{L}}{{P}_{obs , m}} .$$

In some embodiments, a most recently computed k_{t,m} may be stored in the in-memory computation system 106, a different in-memory computation system, the datastores 111, or a different von-Neumann system.

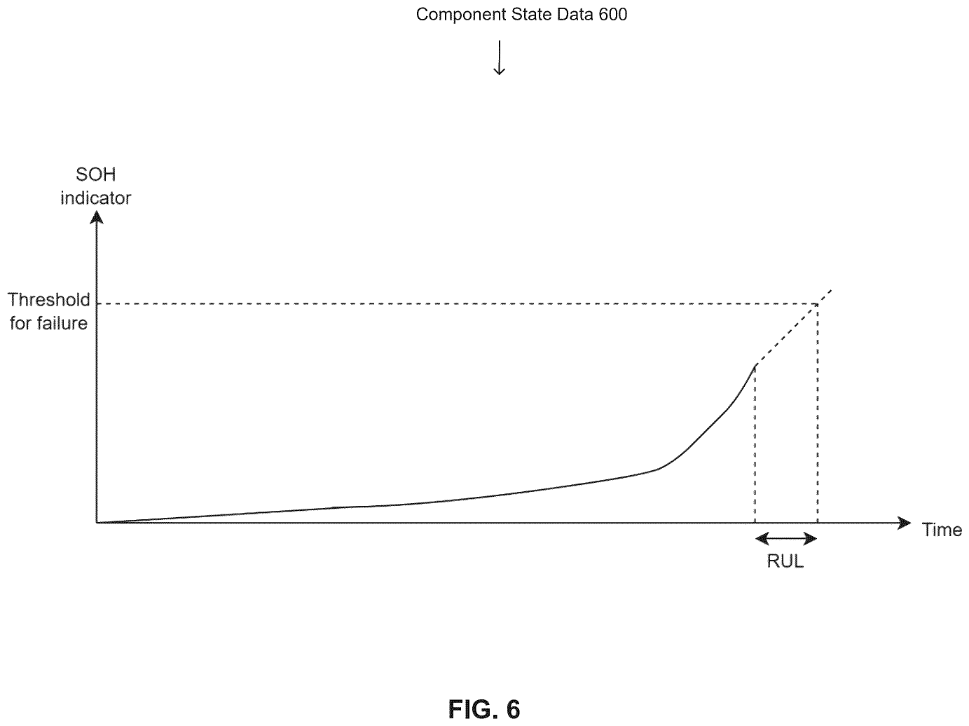

FIG. 6 illustrates example component state data 600, showing rate of change of a component state. In some embodiments, the electronic device prognosis system 122 estimates an RUL of a component by estimating future component states. In some embodiments, the electronic device prognosis system 122 estimates a present or historical rate of change of a component state, and estimate future component states based on estimated present or historical rate of change of the component state. For example, the electronic device prognosis system 122 may estimate future component states based on a linear or non-linear assumption of rate of change of the component state. In some embodiments, the electronic device prognosis system 122 predicts a future time instance at which the component state reaches a threshold condition, which may correspond to a threshold for failure. In some embodiments, the electronic device prognosis system 122 determines a duration between a present time instance and the future time instance as the RUL.

It will be appreciated that the term “or,” as used herein, may be construed in either an inclusive or exclusive sense. Moreover, plural instances may be provided for resources, operations, or structures described herein as a single instance. It will be appreciated that the term “request” or “command” shall include any computer or electronic request or instruction, whether permissive or mandatory.

The datastores (e.g., datastores 111 in FIG. 1) described herein may be any suitable structure (e.g., an active database, a relational database, a self-referential database, a table, a matrix, an array, a flat file, a documented-oriented storage system, a non-relational No-SQL system, and the like), and may be cloud-based or otherwise.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Any reference to “approximate,” “close,” “near,” a “threshold” or “sufficiency” may be construed to encompass any applicable value or degree, such as any applicable value or degree sufficient to satisfy a given outcome. Recitation of numeric ranges of values throughout the specification is intended to serve as a shorthand notation of referring individually to each separate value falling within the range inclusive of the values defining the range, and each separate value is incorporated in the specification as it were individually recited herein. Any reference to “approximate,” “close,” “near,” a “threshold” or “sufficiency” may be construed to encompass values within a certain range of the specified value, such as within 25 percent, 10 percent, 5 percent, 1 percent, 0.5 percent, 0.25 percent, 0.1 percent, or any other applicable value. In other embodiments, “approximate,” “close,” “near,” a “threshold” or “sufficiency” may refer to a value or entity being within a design tolerance or to achieve an objective or result or to satisfy a given outcome, or failing to satisfy a given outcome. For example, a threshold condition may refer to device or component level of health failing to satisfy an operational condition, such that replacement or deactivation of the device is needed.

The phrases “at least one of,” “at least one selected from the group of,” or “at least one selected from the group consisting of,” and the like are to be interpreted in the disjunctive (e.g., not to be interpreted as at least one of A and at least one of B).

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiment.

Additionally, the singular forms “a,” “an” and “the” include plural referents unless the context clearly dictates otherwise.

The present invention(s) are described above with reference to example embodiments. It will be apparent to those skilled in the art that various modifications may be made and other embodiments may be used without departing from the broader scope of the present invention(s). Therefore, these and other variations upon the example embodiments are intended to be covered by the present invention(s).

1. A profiling system comprising:
an electronic component profiling system comprising an in-memory computation system, the in-memory computation system comprising computation circuitry and computation control circuitry, the in-memory computation system configured to profile one or more electronic components that constitute an electronic device by:
obtaining, from one or more sensors of the electronic components, parameters indicative of operating characteristics of electronic components;
computing, by the computation control circuitry and according to programming of the computation circuitry, the component states of the electronic components based on the parameters and a function defining a transformation of the parameters to the component states, the component states indicative of states of health of the electronic components; and
the electronic device profiling system comprising device profiling circuitry is configured to perform:
based on the computed component states and previous component states, predicting future component states of the electronic components;
based on the predicted future component states, predicting one or more future device states of the electronic device; and
outputting information of the predicted one or more future device states.

2. The profiling system of claim 1, wherein predicting the future component states comprises:
predicting corresponding future time instances at which the future component states initially cross a threshold failure condition; and predicting one or more future device states comprises:
based on an earliest predicted future time instance, predicting a remaining useful life (RUL) of the electronic device.

3. The profiling system of claim 1, wherein the computation circuitry comprises word lines and bit lines of computation circuitry elements programmed according to a transformation matrix representing the function, the transformation matrix comprising rows and columns of matrix elements, each column of matrix elements corresponding to a different electronic component and each bit line representing a component state of a different electronic component; and the computation control circuitry is configured to compute the component states by:
generating input electric signals according to values of the parameters;
applying the input electric signals to word lines of corresponding programmed computation circuitry elements to cause changes of electrical attribute magnitudes across the computation circuitry elements, a same input electric signal being applied to programmed computation circuitry elements across a particular word line;
sensing the changes of electrical attribute magnitudes; and
computing the component states based on the sensed changes of the electrical attribute magnitudes.

4. The profiling system of claim 3, wherein:
the computation circuitry elements are programmed to have first electric attribute values of a first electric attribute consistent with the rows and columns of matrix elements;
generating the input electric signals comprises programming the input electric signals according to second electric attribute values of a second electric attribute, the second electric attribute values being consistent with the values of the parameters; and
the changes of electrical attribute magnitudes correspond to a third electric attribute.

5. The profiling system of claim 4, wherein the first electric attribute comprises a conductance, the second electric attribute comprises a voltage, and the third electric attribute comprises a current.

6. The profiling system of claim 3, wherein computing the component states based on the sensed changes of the electrical attribute magnitudes comprises:
aggregating the changes of electrical attribute magnitudes across computation circuitry elements corresponding to a particular bit line to compute the component state of a particular component corresponding to the particular bit line.

7. The profiling system of claim 3, wherein the in-memory computation system comprises read/write trigger control circuitry configured to:
generate a write trigger or a read trigger to cause the changes of electrical attribute magnitudes to be written into or read from memory cells corresponding to the computation circuitry elements, the memory cells being colocated with the computation circuitry elements; and
apply the write trigger or the read trigger to one or more bit lines of the computation circuitry elements in response to applying of the input electric signals to word lines of corresponding programmed computation circuitry elements.

8. The profiling system of claim 7, wherein the write trigger comprises a first voltage pulse and the read trigger comprises a second voltage pulse, the write trigger having a higher magnitude compared to the read trigger.

9. The profiling system of claim 7, wherein the in-memory computation system comprises output control circuitry configured to:
detect the write trigger or the read trigger;
in response to detecting the write trigger or the read trigger, write the changes of electrical attribute magnitudes to one or more memory cells or retrieve the changes of electrical attribute magnitudes from one or more memory cells corresponding to selected computation circuitry elements indicated by the write trigger or the read trigger.

10. The profiling system of claim 1, wherein the in-memory computation system comprises a memristor array.

11. A method implemented by a profiling system, the profiling system comprising an electronic component profiling system, the electronic component profiling system comprising an in-memory computation system, the in-memory computation system comprising computation circuitry and computation control circuitry, the profiling system comprising an electronic device profiling system, the method comprising:
obtaining, from one or more sensors of the electronic components, parameters indicative of operating characteristics of electronic components;
computing, by the computation control circuitry and according to programming of the computation circuitry, component states of the electronic components based on the parameters of the electronic components and a function defining a transformation of the parameters to the component states, the component states indicative of states of health of the electronic components;
based on the computed component states and previous component states, predicting, by the electronic device profiling system, future component states of the electronic components;
based on the predicted future component states, predicting, by the electronic device profiling system, one or more future device states of the electronic device; and
outputting, by the electronic device profiling system, information of the predicted one or more future device states.

12. The method of claim 11, wherein predicting the future component states comprises:
predicting corresponding future time instances at which the future component states initially cross a threshold failure condition; and predicting one or more future device states comprises:
based on an earliest predicted future time instance, predicting a remaining useful life (RUL) of the electronic device.

13. The method of claim 11, wherein the computation circuitry comprises word lines and bit lines of computation circuitry elements programmed according to a transformation matrix representing the function, the transformation matrix comprising rows and columns of matrix elements, each column of matrix elements corresponding to a different electronic component and each bit line representing a component state of a different electronic component; and computing the component states comprises:
generating input electric signals according to values of the parameters;
applying the input electric signals to word lines of corresponding programmed computation circuitry elements to cause changes of electrical attribute magnitudes across the computation circuitry elements, a same input electric signal being applied to programmed computation circuitry elements across a particular word line;
sensing the changes of electrical attribute magnitudes; and
computing the component states based on the sensed changes of the electrical attribute magnitudes.

14. The method of claim 13, wherein:
the computation circuitry elements are programmed to have first electric attribute values of a first electric attribute consistent with the rows and columns of matrix elements;
generating the input electric signals comprises programming the input electric signals according to second electric attribute values of a second electric attribute, the second electric attribute values being consistent with the values of the parameters; and
the changes of electrical attribute magnitudes correspond to a third electric attribute.

15. The method of claim 14, wherein the first electric attribute comprises a conductance, the second electric attribute comprises a voltage, and the third electric attribute comprises a current.

16. The method of claim 13, wherein computing the component states based on the sensed changes of the electrical attribute magnitudes comprises:
aggregating the changes of electrical attribute magnitudes across computation circuitry elements corresponding to a particular bit line to compute the component state of a particular component corresponding to the particular bit line.

17. The method of claim 16, wherein the in-memory computation system comprises read/write trigger control circuitry, and the method further comprises:
generating, by the read/write trigger control circuitry, a write trigger or a read trigger to cause the changes of electrical attribute magnitudes to be written into or read from memory cells corresponding to the computation circuitry elements, the memory cells being colocated with the computation circuitry elements; and
applying, by the read/write trigger control circuitry, the write trigger or the read trigger to one or more bit lines of the computation circuitry elements in response to applying of the input electric signals to word lines of corresponding programmed computation circuitry elements.

18. The method of claim 17, wherein the write trigger comprises a first voltage pulse and the read trigger comprises a second voltage pulse, the write trigger having a higher magnitude compared to the read trigger.

19. The method of claim 17, wherein the in-memory computation system comprises output control circuitry, and the method further comprises:
detecting, by the output control circuitry, the write trigger or the read trigger; and
in response to detecting the write trigger or the read trigger, writing the changes of electrical attribute magnitudes to one or more memory cells or retrieving the changes of electrical attribute magnitudes from one or more memory cells corresponding to selected computation circuitry elements indicated by the write trigger or the read trigger.

20. The method of claim 11, wherein the in-memory computation system comprises a memristor array.
